(19) United States
(12) Patent Application Publication
(10) Pub. No.: US 2013/0334594 A1
(43) Pub. Date: Dec. 19, 2013

(54) RECESSED GATE MEMORY APPARATUSES AND METHODS

(71) Applicants: Jerome A. Imonigie, Boise, ID (US); Patrick M. Flynn, Boise, ID (US); Sandra L. Tagg, Boise, ID (US); Prashant Raghu, Boise, ID (US)

(72) Inventors: Jerome A. Imonigie, Boise, ID (US); Patrick M. Flynn, Boise, ID (US); Sandra L. Tagg, Boise, ID (US); Prashant Raghu, Boise, ID (US)

(21) Appl. No.: 13/524,803

(22) Filed: Jun. 15, 2012

(51) Int. Cl. H01L 29/792; H01L 21/28; H01L 21/306

(52) U.S. Cl. 257/326; 438/706; 438/589; 257/E29.309; 257/E21.215; 257/E21.19

(57) ABSTRACT

Some embodiments include a memory device and a method of forming the memory device. One such memory device includes a string of stacked memory cells. Each of the memory cells in the string includes a charge storage structure and a recessed control gate. The recessed control gate has a substantially smooth surface separated from the charge storage structure by dielectric material. One such method includes etching heavily boron doped polysilicon selective to oxide to form a recessed control gate having a surface with nubs. A smoothing solution is applied to the surface of the recessed control gate to smoothen the nubs. Additional apparatuses and methods are described.

### BACKGROUND

Various types of memory devices are used in many electronic products to store data and other information. Increasingly, memory devices are being reduced in size to achieve a higher density for storage capacity. However, difficulties in fabrication of higher density memory devices can result in decreased reliability.

### BRIEF DESCRIPTION OF THE DRAWINGS

FIG. 1 shows a block diagram of a memory device having a memory array with memory cells, according to an embodiment.

FIG. 2A shows a cross-sectional, three-dimensional schematic representation of a memory device, according to an embodiment.

FIG. 2B shows an isometric cut-away representation of a highlighted portion of the memory device of FIG. 2A, according to an embodiment.

FIG. 3 through FIG. 27 show various processes of forming a memory device, according to an embodiment.

### DETAILED DESCRIPTION

The description that follows includes illustrative apparatuses (circuitry, devices, structures, systems, and the like) and methods (e.g., processes, protocols, sequences, techniques, and technologies) that embody the inventive subject matter of the present disclosure. In the following description, for purposes of explanation, numerous specific details are set forth in order to provide an understanding of various embodiments of the inventive subject matter. It will be evident, however, to those of ordinary skill in the art that various embodiments of the inventive subject matter may be practiced without these specific details. Further, well-known apparatuses and methods have not been shown in detail so as not to obscure the description of various embodiments.

As used herein, the term “or” may be construed in an inclusive or exclusive sense. Additionally, although various exemplary embodiments discussed below may primarily focus on two-state (e.g., single level cell (SLC)) NAND memory devices, the embodiments are merely given for clarity of disclosure, and thus, are not limited to apparatuses in the form of NAND or NOR memory devices or even to memory devices in general.

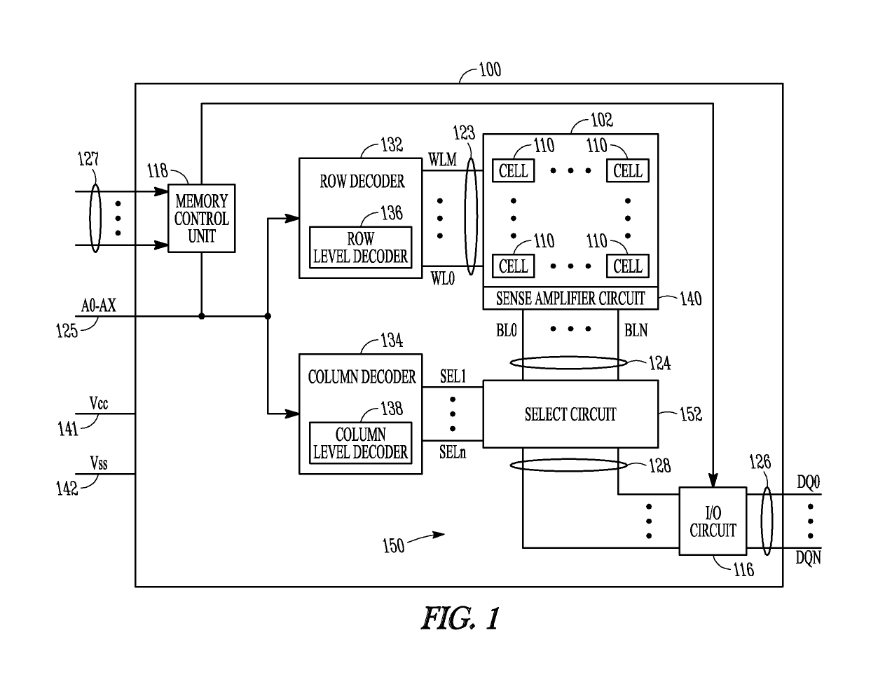

FIG. 1 shows a block diagram of a memory device 100 having a memory array 102 with memory cells 110 according to an embodiment of the invention. Memory cells 110 can be arranged in rows and columns along with access lines 123 (e.g., wordlines having signals WL0 through WLM) and first data lines 124 (e.g., bit lines having signals BL0 through BLN). Memory device 100 uses first data lines 124 and second data lines 128 to transfer information within memory cells 110. Memory cells 110 can be physically located in multiple device levels such that one group of memory cells 110 can be stacked on one or more groups of other memory cells 110. Row decoder 132 and column decoder 134 decode address signals A0 through AX on lines 125 (e.g., address lines) to determine which memory cells 110 are to be accessed. Row and column level decoders 136 and 138 of row and column decoders 132 and 134, respectively, determine on which of the multiple device levels of memory device 100 that the memory cells 110 to be accessed are located.

A sense amplifier circuit 140 operates to determine the value of information read from memory cells 110 and provide the information in the form of signals to first data lines 124 and second data lines 128. Sense amplifier circuit 140 can also use the signals on first data lines 124 and second data lines 128 to determine the value of information to be written to memory cells 110. Memory device 100 can include circuitry 150 to transfer information between memory array 102 and input/output lines 126. Signals DQ0 through DQN on input/output lines 126 can represent information read from or written into memory cells 110. Input/output lines 126 can include nodes within memory device 100 or nodes (e.g., pins or solder balls) on a package where memory device 100 resides. Other devices external to memory device 100 (e.g., a memory controller or a processor) may communicate with memory device 100 through address lines 125, input/output lines 126, and control lines 127.

Memory device 100 performs memory operations such as a read operation to read information from memory cells 110 and a write operation (sometime referred to as a programming operation) to store information into memory cells 110. A memory control unit 118 controls the memory operations based on control signals on control lines 127. Examples of the control signals on control lines 127 include one or more clock signals and other signals to indicate which operation, (e.g., a write or read operation) that memory device 100 performs. Other devices external to memory device 100 (e.g., a processor or a memory controller) may control the values of the control signals on control lines 127. Specific values of a combination of the signals on these lines can produce a command (e.g., a write or read command) that causes memory device 100 to perform a corresponding memory operation (e.g., a write or read operation).

Each of memory cells 110 can store information representing a value of a single bit or a value of multiple bits such as two, three, four, or other numbers of bits. For example, each of memory cells 110 can store information representing a binary value “0” or “1” of a single bit. In another example, each of memory cells 110 can store information representing a value of multiple bits, such as one of four possible values “00”, “01”, “10”, and “11” of two bits, one of eight possible values “000”, “001”, “010”, “011”, “100”, “101”, “110” and “111, or one of other values of other number of multiple bits.

Memory device 100 can receive a supply voltage, including supply voltage signals Vcc and Vss, on lines 141 and 142, respectively. Supply voltage signal Vss may operate at a ground potential (e.g., having a value of approximately zero volts). Supply voltage signal Vcc may include an external voltage supplied to memory device 100 from an external power source such as a battery or an alternating-current to direct-current (AC-DC) converter.

Circuitry 150 of memory device 100 can include a select circuit 152 and an input/output (I/O) circuit 116. Select circuit 152 responds to signals SEL0 through SELn to select the signals on first data lines 124 and second data lines 128 that can represent the information read from or written into memory cells 110. Column decoder 134 selectively activates the SEL0 through SELn signals based on address signals A0 through AX. Select circuit 152 selects the signals on first data lines 124 and second data lines 128 to provide communication between memory array 102 and I/O circuit 116 during read and writes operations.

Memory device 100 can be a non-volatile memory device and memory cells 110 can be non-volatile memory cells such that memory cells 110 can retain information stored thereon when power (e.g., Vcc or Vss, or both) is disconnected from memory device 100. For example, memory device 100 can be a flash memory device such as a NAND flash or a NOR flash memory device, or other kinds of memory devices, such as a variable resistance memory device (e.g., phase change random-access-memory (PCRAM), resistive RAM (RRAM), etc.).

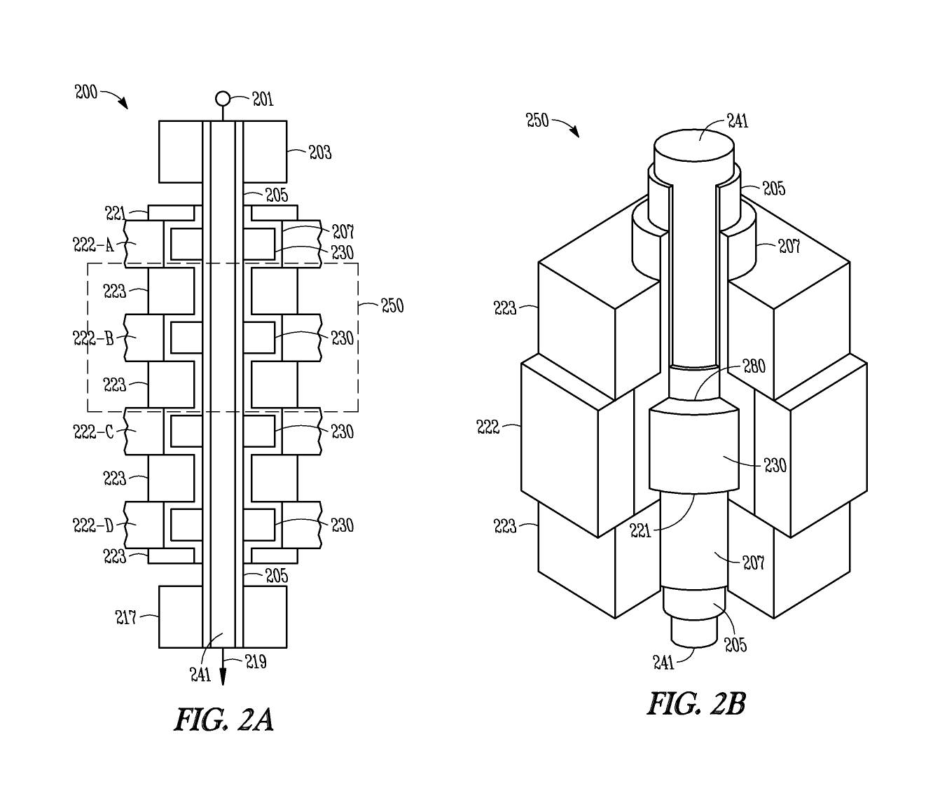

One of ordinary skill in the art may recognize that memory device 100 may include other features and components that are not shown in FIG. 1; these have not been shown to help retain focus on the embodiments described herein. The memory device 101 may include devices and memory cells, and operate using memory operations (e.g., programming and erase operations) similar to or identical to those described below with reference to various other figures and embodiments discussed herein. Memory device 100 and/or array 102 may include at least one of the memory devices and memory cells 110 described below with reference to FIG. 2 through FIG. 27.

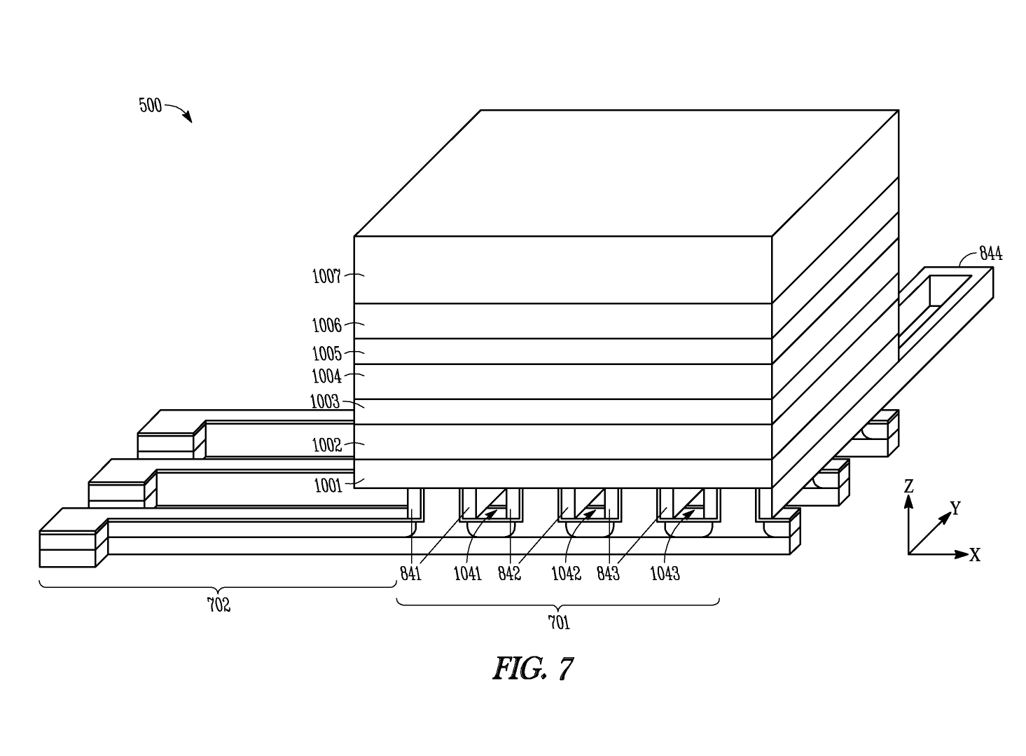

With reference now to FIG. 2A, a cross-sectional, three-dimensional schematic representation of a memory device 200 is shown and includes a drain select-gate transistor 203, a number of recessed gates (e.g., recessed control gates) 222-A, 222-B, 222-C, and 222-D and a number of spaced-apart charge storage structures 230 (e.g., floating gates). A recessed gate can be a gate with a solution smoothened outer surface, as described herein. In an embodiment, three-dimensional memory device 200 can include a plurality of recessed gates. The number of recessed gates can be separated by a material 223 (e.g., 1001, 1003, 1005, and 1007, FIG. 7) The memory device 200 also includes a dielectric (e.g., a tunnel oxide) 205 disposed between a pillar 241 of conductive material and each of the number of charge storage structures 230. As will be better understood with reference to the ensuing figures, the pillar 241 may comprise a pillar of semiconductor material (e.g., conductively doped polysilicon) having a substantially circular cross-section with the dielectric 205 formed on and surrounding an outer periphery of the pillar 241. In other examples, the pillar 241 may take on other cross-sectional shapes such as substantially square, rectangular, elliptical, or a number of other geometrical profiles. The pillar 241 is selectively electrically coupled to a source (e.g., a source line) (not shown) by a source select-gate transistor 217.

A person of ordinary skill in the art will appreciate that a memory cell string is typically formed from a number of cells coupled together in series. For example, a NAND string may comprise, for example, 8, 16, 32, or any other number of cells between two select gates. However, FIG. 2A is shown to include only four memory cells 250 for illustrative purposes. The person of ordinary skill in the art will understand the inventive subject matter described herein is readily scalable to any number of memory cells. Further, the memory cells can be coupled in series or parallel, or in various other combinations.

With continuing reference to FIG. 2A, each of the recessed gates 222-A, 222-B, 222-C, and 222-D are separated from a respective one of the charge storage structures 230 by at least a dielectric material 207. Embodiments include an oxide, nitride, and oxide (ONO) dielectric material. In various embodiments, the dielectric material 227 can be a high dielectric constant (high-κ) material such as an inter-poly dielectric (IPD) material. Generally, a high dielectric constant material may be considered as any material having a dielectric constant equal to or greater than the dielectric constant of silicon dioxide (SiO₂). The dielectric constant for SiO₂ is approximately 3.9.

FIG. 2B shows an isometric cut-away representation of a memory cell 250 of the memory device 200 of FIG. 2A. Each of the labeled cells are similar to the components discussed with reference to FIG. 2A, above. The memory cell 250 is shown as having a charge storage structure 230 that has a substantially-toroidal structure (i.e., a toroid) surrounding the pillar 241. However, each of the number of charge storage structures 230 can be formed in a variety of shapes. Additionally, although a substantially toroidally-shaped version of the charge storage structure 230 is shown, a person of ordinary skill in the art can readily adapt formation processes to a number of feature geometries upon reading and understanding the disclosure and figures provided herein. For example, the charge storage structures 230 can take on a number of different shapes and geometries including substantially square, substantially rectangular, and substantially stadium-like (i.e., a geometrical form) structures. Each of these geometries has an inner surface 280 in contact with the dielectric 205 (e.g., to allow Fowler-Nordheim tunneling of electrons into the charge storage structure 230), and also an outer surface 281.

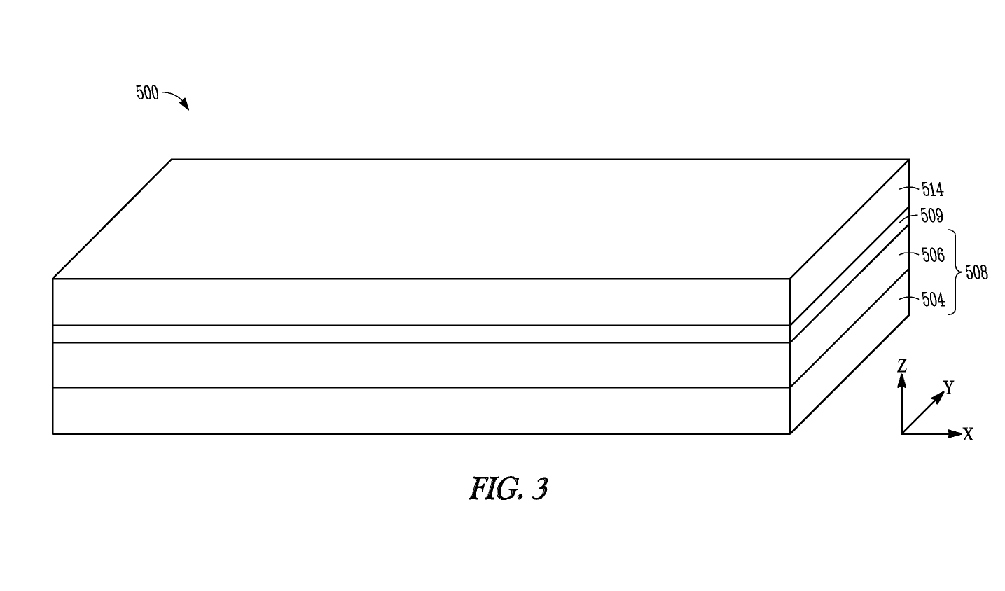

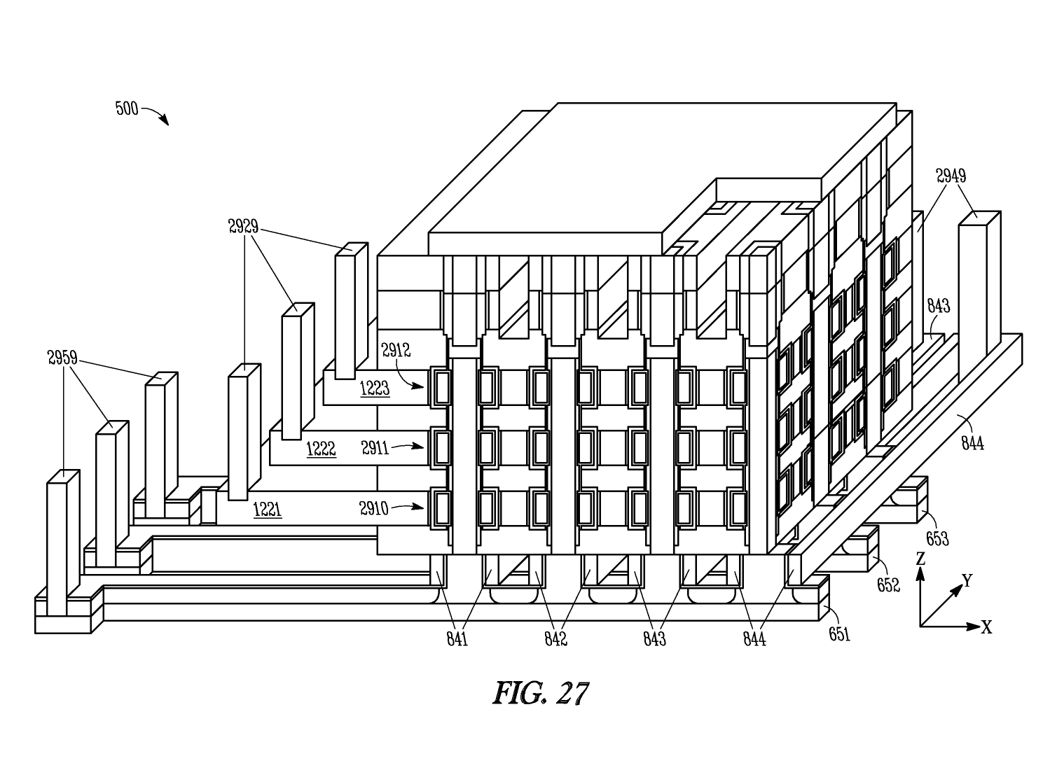

FIG. 3 through FIG. 27 show various processes of forming a memory device 500 having data lines located below memory cells, according to an embodiment of the invention. The fabrication process of memory device 500 (shown in more detail in FIG. 27) begins in FIG. 3, and may be similar to or identical to the memory device 200 of FIG. 2A. FIG. 3 through FIG. 27 show an architecture where data lines are on the top of the memory device, however embodiments are not so limited. For example, the data lines can be on the top of the memory device.

FIG. 3 shows a base 508, which can include materials 504 and 506. Material 504 can include bulk silicon or could be another semiconductor material. Material 506 can be a dielectric material, for example, silicon oxide. FIG. 3 also shows materials 509 and 514 formed over base 508. Forming materials 509 and 514 can include depositing a conductive material over base 508 and then depositing another conductive material over material 509. Material 509 can include a metal or other conductive materials. Material 514 can include undoped polysilicon or doped polysilicon, such as p-type silicon or another conductive material.

FIG. 3 also shows an X-direction, a Y-direction substantially perpendicular to the X-direction, and a Z-direction substantially perpendicular to both the X-direction and the Y-direction. As shown in FIG. 3, materials 509 and 514 can be formed in the Z-direction.

As used herein, the term “on” used with respect to two or more materials, one “on” the other, means at least some contact exists between the materials, while “over” or “overlaying” can refer to a material being “on” another material, or to the situation where one or more additional intervening materials exist between the materials, one of which is over or overlaying the other (e.g., contact is not necessarily required). The term “on”, “over”, or “overlaying” does not imply any directionality as used herein unless otherwise explicitly stated.

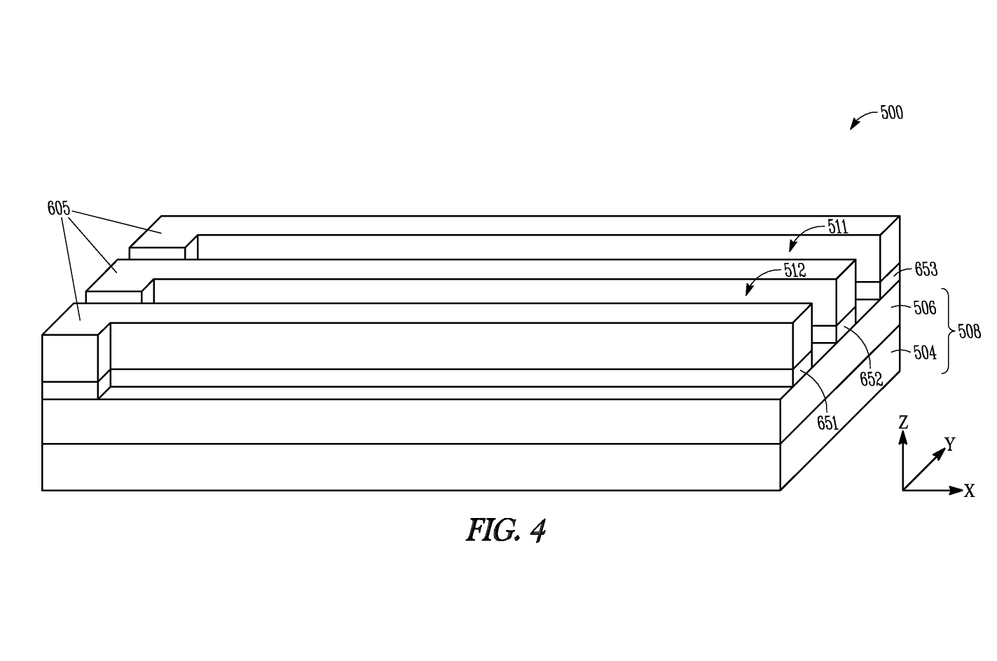

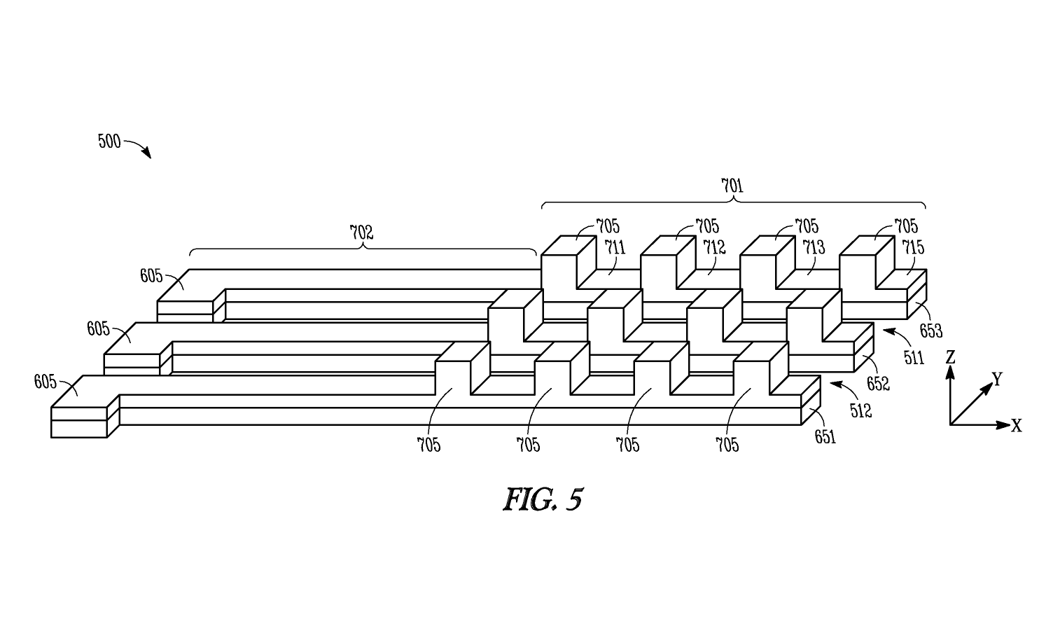

FIG. 4 shows the process of constructing the memory device 500 after data lines 651, 652, and 653 and structures 605 have been formed. A process such as etching (e.g., dry or wet etching) can be used to remove portions of materials 509 and 514 (FIG. 3) to form trenches 511 and 512, which have trench bottoms defined by material 506. Each of data lines 651, 652, and 653 and each of structures 605 has a greater dimension (e.g., length) extending in the X-direction. A mask (not shown in FIG. 4) having separate openings extending in the X-direction can be used to form trenches 511 and 512. As shown in FIG. 4, trenches 511 and 512 divide material 509 (FIG. 4) into separate data lines 651, 652, and 653, and divide material 514 (FIG. 5) into different structures 605.

FIG. 5 shows the process of constructing the memory device 500 after pillars 705 have been formed in first area 701 of memory device 500. Pillars 705 are not formed in second area 702 of memory device 500. For simplicity, FIG. 5 through FIG. 27 do not show base 508 of FIG. 4. In FIG. 5, a process such as etching can be used to remove portions of structures 605 to form trenches 711, 712, 713 and 715 in the Y-direction, substantially perpendicular to trenches 511 and 512, such that pillars 705 can be formed as shown in FIG. 5. A mask (not shown in FIG. 5) having separate openings extending in the Y-direction can be used to form trenches 711, 712, 713 and 715. Each pillar 705 can be formed to a height in the Z-direction of approximately 20 to 50 nanometers. As shown in FIG. 5, pillars 705 are arranged in rows and columns (e.g., in a matrix) in the X-direction and Y-direction. For simplicity, FIG. 5 does not show a dielectric material filled in trenches 511 and 512. However, forming memory device 500 in FIG. 5 also can include forming a dielectric material (e.g., silicon oxide) to fill trenches 511 and 512 up to a top surface of the pillars 705.

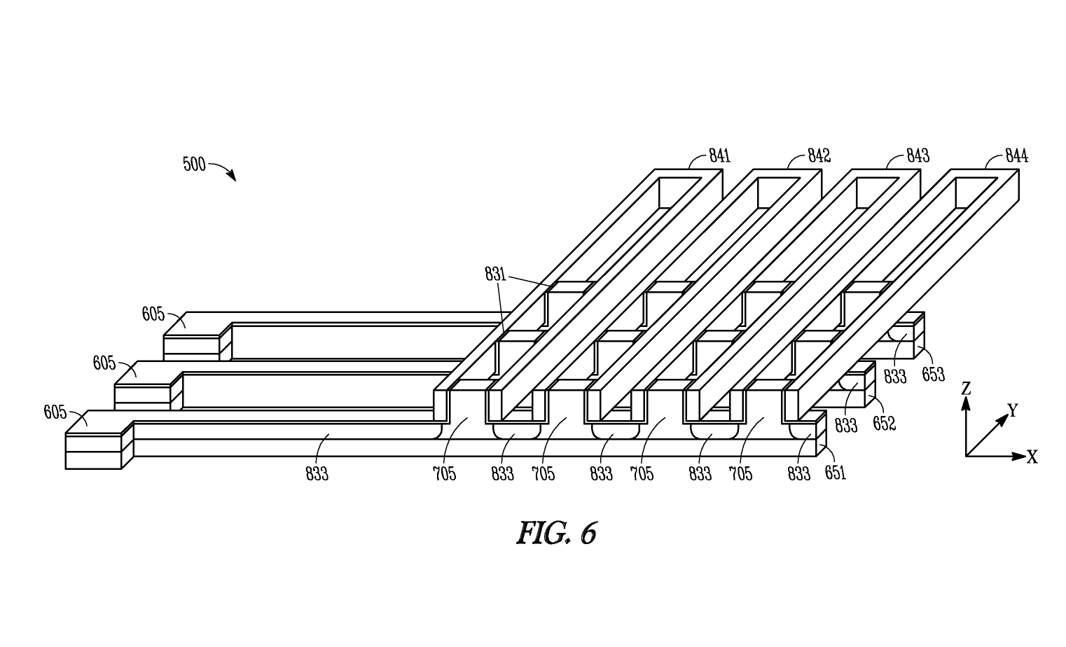

FIG. 6 shows the process of constructing the memory device 500 after dielectric 831 and drain select gate lines 841, 842, 843, and 844 have been formed. In FIG. 6, dielectrics 831 are formed to electrically isolate drain select gate lines 841, 842, 843, and 844 from pillars 705. Dielectrics 831 can be formed by, for example, depositing a dielectric material (e.g., silicon oxide) on at least two sides of each pillar 705 or by oxidizing pillars 705. After dielectrics 831 are formed, drain select gate lines 841, 842, 843, and 844 can be formed by, for example, depositing a conductive material over pillars 705 and trenches 711, 712, and 713 (FIG. 5) and then removing (e.g., etching) a portion of the conductive material to form drain select gate lines 841, 842, 843, and 844 having the structure shown in FIG. 6. Examples of the conductive materials that can be use to form drain select gate lines 841, 842, 843, and 844 include polysilicon, metal, or other conductive materials, such as TiN and TaN.

FIG. 6 also shows doped regions 833, which can be formed by inserting (e.g., implanting) n-type impurities into selective portions of structure 605. Examples of n-type impurities include phosphorus (P) or arsenic (As). The remaining portion of structures 605 into which n-type impurities have not been inserted may maintain its original material characteristics, such as p-type silicon, as described above with reference to FIG. 3.

FIG. 7 shows the process of constructing the memory device 500 after materials 1001 through 1007 are formed over pillars 705 and drain select gate lines 841, 842, 843, and 844. Materials 1001 through 1007 can be formed in the first and second areas 701 and 702 of memory device 500. However, to retain focus on the description of the fabrication process illustrated herein, FIG. 7 does not show some portions of materials 1001 through 1007 in the second area 702.

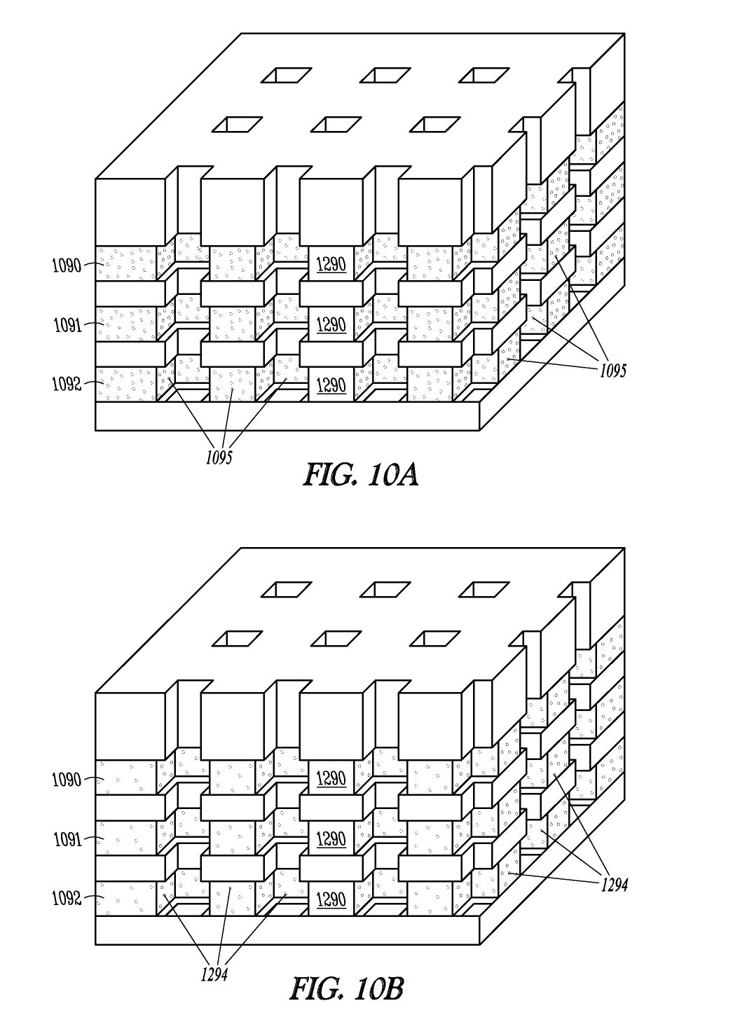

In FIG. 7 through FIG. 27, for simplicity, some number designations associated with some components of memory device 500 may not be repeated from one figure to another figure. In FIG. 7, before forming materials 1001 through 1007, a dielectric material (not shown in FIG. 10), such as silicon oxide, can be formed to fill gaps 1041, 1042, and 1043. Forming materials 1001 through 1007 can include alternately depositing dielectric material and conductive material in an interleaved fashion, such that these materials are alternately stacked over each other in the Z-direction, as shown in FIG. 7. Materials 1001, 1003, 1005, and 1007 can include dielectric materials, such as silicon oxide. Materials 1002, 1004, and 1006 can include conductive materials, such as metal or polysilicon (e.g., n-doped or p-doped polysilicon). As shown in FIG. 7, materials 1001 through 1007 are formed such that materials 1002, 1004, and 1006 are electrically isolated from each other by materials 1001, 1003, 1005, and 1007. In some embodiments, materials 1002, 1004, and 1006 can include boron doped polysilicon, such as heavily boron doped polysilicon, such as 1×10²¹ atoms/cm³.

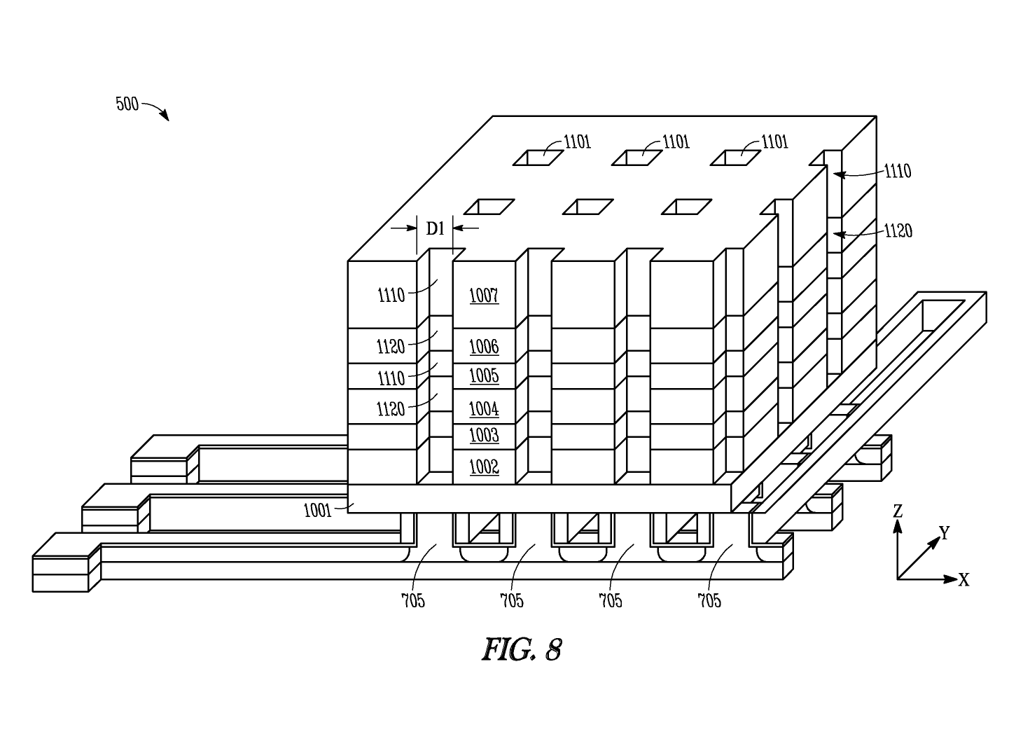

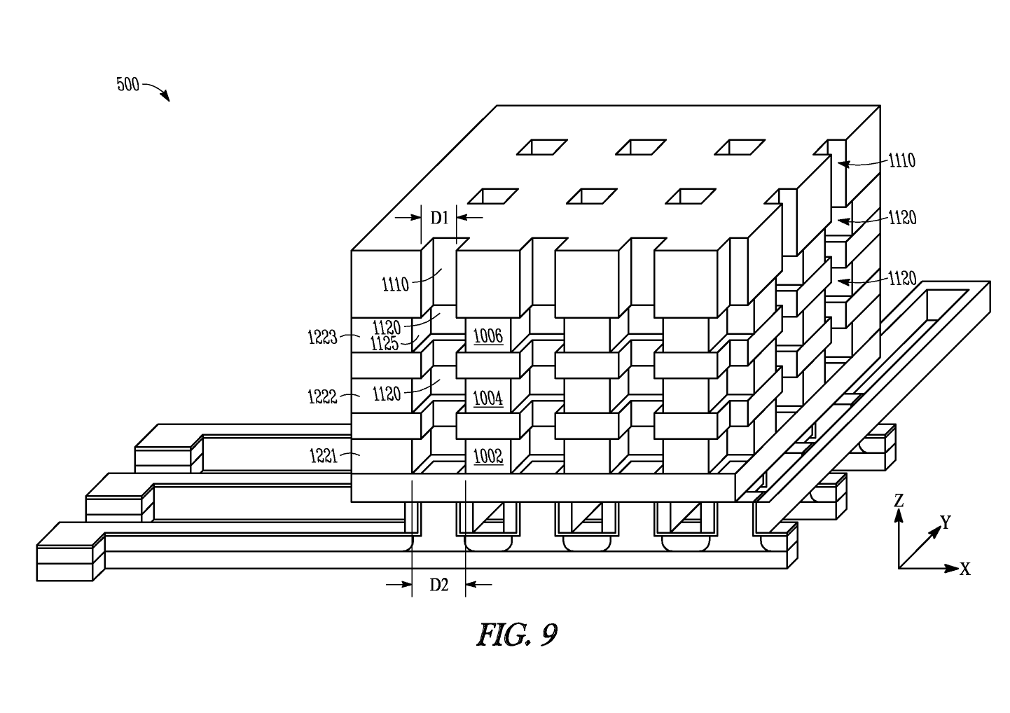

FIG. 8 shows the process of constructing the memory device 500 after openings (e.g., holes) 1101 have been formed in material 1002 through 1107. Holes 1101 are formed such that each hole 1101 can be aligned substantially directly over a corresponding pillar 705, as illustrated in FIG. 8. Forming the holes 1101 can include removing (e.g., etching) a portion of each of materials 1002 through 1007, stopping at material 1001, such that some, or all of the material 1001 remains to separate holes 1101 from pillars 705. Forming holes 1101 results in forming cavities 1110 in each of materials 1003, 1005, and 1007, and cavities 1120 in each of materials 1002, 1004, and 1006. As shown in FIG. 9, cavities 1110 in the materials 1003, 1005, and 1007 are substantially aligned directly over cavities 1120 in the other materials 1002, 1004, and 1006. Each cavity 1110 and each cavity 1120 may have substantially the same diameter, D1. Diameter D1 can also be considered the diameter of each hole 1101 at the location of each of the cavities 1110 and 1120.

FIG. 9 shows the process of constructing the memory device 500 after cavities 1120 have been formed in materials 1002, 1004, and 1006 (to form gates 1090, 1091, and 1092, FIG. 10A). Forming cavities 1120 can include enlarging the size of cavities 1120 (FIG. 8) while keeping the size of cavities 1110 substantially unchanged (e.g., remaining substantially at diameter D1). For example, enlarging the size of cavities 1120 (FIG. 8) can include selectively removing (e.g., selective etching) a portion of each of materials 1002, 1004, and 1006 at each cavity 1120 (FIG. 8) such that the diameter of each cavity 1220 increases to substantially diameter D2, while the diameter D1 at each cavity 1110 remains substantially unchanged. Diameter D2 is greater than diameter D1. Enlarging the cavities 1120 in materials 1002, 1004, and 1006 forms recessed gates 1090, 1091, and 1092 (see FIG. 10A). After a smoothing process, as described herein, gates 1090, 1091, and 1092 become substantially smooth recessed gates 1221, 1222, and 1223.

Forming the recessed gates 1090, 1091, and 1092 of FIG. 10A can include etching heavily boron doped polysilicon selective to oxide. During the process of forming the gates 1090, 1091, and 1092, a number (e.g., one or more) of polysilicon nubs 1095 can inadvertently be formed. A polysilicon nub is a protrusion from a surface of the polysilicon that, in the absence of polysilicon nubs, would be substantially smooth. In other words, the polysilicon nubs 1095 roughen the surface of the polysilicon.

A “substantially smooth” surface can be an outer surface of a polysilicon gate that marginally, if at all, contributes to cell leakage. Recessed gates 1221, 1222, 1223, and 1224 of FIG. 10B have a substantially smooth surface 1290. For example, recessed gates 1221, 1222, 1223, and 1224 include a solution smoothened surface 1290. The solution smoothened surface 1290 can include smoothened polysilicon nubs 1294.

Cavities 1120 can typically be enlarged via a wet etching chemistry. However, common wet etching chemistries are not effective in selectively etching heavily boron doped polysilicon. A fluorinated vapor phase chemistry can be used to etch boron doped silicon because it can be selective to oxide. However, such vapor phase chemistry etching can lead to the formation of polysilicon nubs, which can lead to cell leakage.

By smoothing the polysilicon nubs (e.g., reducing the number of polysilicon nubs or at least reducing the dimensions of the polysilicon nubs), the potential for cell leakage can be reduced.

After the gates 1090, 1091, and 1092 are formed (e.g., by multiple cycling of fluorinated vapor phase chemistry, a smoothing solution can be applied to smooth a number of polysilicon nubs on an outer surface of the gate. The smoothing solution can include a wet etching chemistry. In one or more embodiments, the solution comprises nitric acid and/or hydrofluoric acid. In one or more embodiments, the smoothing solution can also comprise a complexing agent (e.g., oxalic acid). Examples of complexing agents include, but are not limited to: ethylene diaminetetraacetic acid (EDTA), diethylene triaminepentaacetic acid (DTPA), h-(hydroxyethyl)-ethylenediaminetriacetic acid (HEDTA), diethylene triaminepentakis-methylenephosphonic acid (DTPMP), nitrilotriacetic acid (NTA), triethylenetetraaminehexaacetic acid (TTHA), N-bis-[2-1,2-dicarboxyethoxyethyl]glycine (BCA5), N-bis-[2-1,2-dicarboxyethoxyethyl]aspartic acid (BCA6), 8-alaninediacetic acid (8-ADA), methylglycinediacetic acid (MGDA), citric acid, maleic acid, gluconic acid, acetic acid, oxalic acid, malonic acid, succinic acid, glutaric acid, adipic acid, pimelic acid, suberic acid, azelaic acid, sebacic acid, undecanedioic acid, brassylic acid, tetradecanedioic acid, thapsic acid, and octadecanedioic acid. In an example, in addition to or instead of a complexing agent, the smoothing solution can also comprise deionized water (DI).

A smoothing solution can include, for example, up to 0.5 weight percent (wt %) of the solution of hydrofluoric acid. A benefit of a solution having 0.5 wt % or less of hydrofluoric acid can include reducing the rate at which exposed oxide of the memory device will be etched by the solution. In an example, the solution can also include oxalic acid up to 10 weight percent (wt %) of the solution. In a specific embodiment, for example, a solution consists of (e.g., consists essentially of) approximately: 31.88 wt % DI, 67.83 wt % nitric acid, 0.21 wt % oxalic acid, and 0.078 wt % hydrofluoric acid.

In an example, the vapor phase chemistry can include vapor fluorine, vapor ammonia, or combinations thereof. Smoothing the outer surface of a formed gate can occur for a particular time, where the particular time is based on a threshold oxide loss value. Exposure to hydrofluoric acid can etch an oxide layer of the memory device. A threshold oxide loss of 5% thickness, for example, of the oxide layer can correlate to a vapor etch time of 30 minutes. In an example, the outer surface of the gate can be smoothened in a temperature range of about 10 degrees Celsius (° C.) to 95° C. A temperature for smoothing can, for example, be determined based on rate of etch, level of oxide selective, level of doping, solution formulation, hydrofluoric concentration, etc.

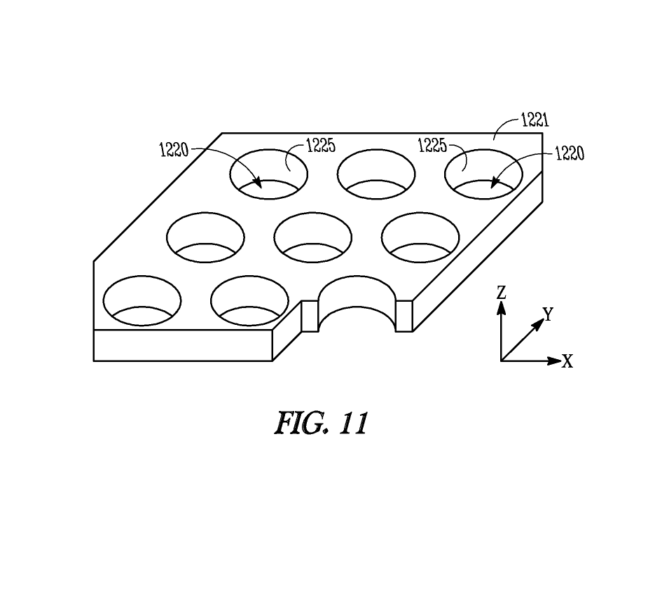

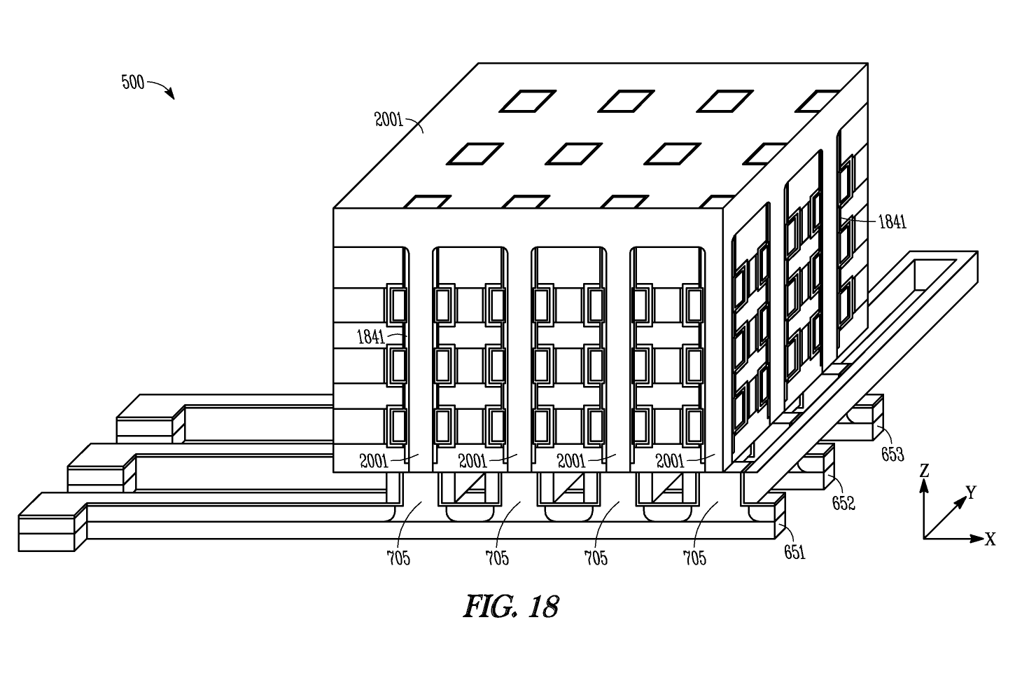

FIG. 11 shows more details of the recessed gate 1221 of FIG. 9. Recessed gates 1222 and 1223 of FIG. 9 can have a structure that is similar to that of recessed gate 1221. As shown in FIG. 11, recessed gate 1221 can include a homogeneous material with cavities 1220 of FIG. 18 being arranged in rows and columns in the X-direction and Y-direction. Each cavity 1220 can include a sidewall 1225.

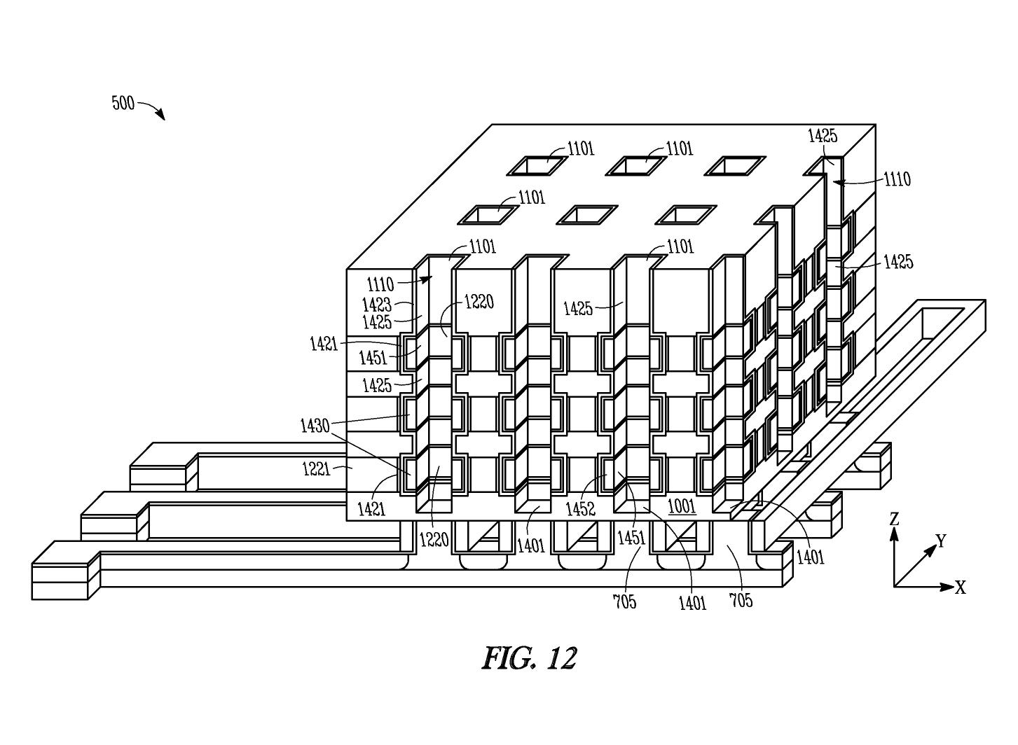

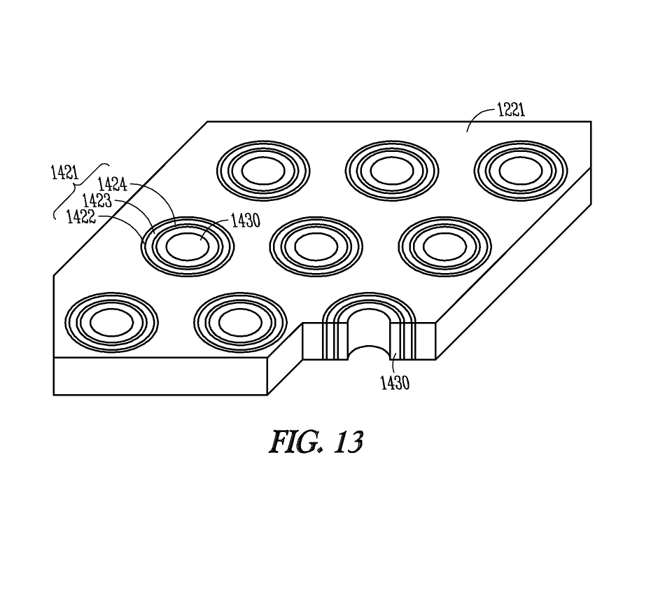

FIG. 12 and FIG. 13 show the process of constructing the memory device 500 after dielectrics 1421 and charge storage structures (e.g., polysilicon floating gates) 1430 have been formed in cavities 1220. Each dielectric 1421 can be formed on sidewall 1225, so that each dielectric 1421 can be located between the material of each recessed gate 1221 and the respective charge storage structure 1430, and so that each charge storages structure 1430 can be electrically isolated from the material of the respective recessed gate 1221 by at least a portion of dielectric 1421. The activity of forming the dielectric 1421 can include forming multiple materials 1422, 1423, and 1424 at different times, one material after another. Forming material 1422 can include oxidizing a portion (e.g., a surface) of sidewall 1225 to form dielectric material (e.g., silicon oxide) on the sidewall 1225. Alternatively and/or additionally, forming material 1422 can include depositing dielectric material (e.g., silicon oxide) on the sidewall 1225. Forming material 1423 can include depositing dielectric material (e.g., silicon nitride) on material 1422, wherein a portion of that dielectric material may also form on the sidewall 1425 of each cavity 1110. Forming material 1424 can include depositing dielectric material (e.g., silicon oxide) on material 1423.

Charge storage structures 1430 can be formed after dielectrics 1421 are formed. As shown in FIG. 13, each charge storage structure 1430 has a ring shape (e.g., a donut shape) with an inner side 1451 and an outer side 1452. Forming charge storage structures 1430 can include depositing a material in holes 1101 (see FIG. 12). Since cavities 1220 of FIG. 12 are substantially aligned with cavities 1110, the material (that forms memory cell 1430) may fill both cavities 1110 and 1120. Then, a portion (e.g., center portion in each hole) of the material that forms charge storage structures 1430 can be removed (e.g., etched) such that the material in cavities 1110 can be removed (e.g., completely removed) and the material in cavities 1220 is not completely removed but partially removed. As shown in FIG. 12, after the material that forms charge storage structures 1430 is removed from cavities 1110, a portion of dielectric material 1423 (e.g., silicon nitride, that was formed on material 1422) may be exposed. As shown in FIG. 12, after the material that forms charge storage structures 1430 is partially removed from cavities 1220, memory cell charge storage structures (formed by the remaining material in a cavity 1220) associated with the same hole 1101 may have its inner side 1451 substantially aligned with sidewall 1425 (or sidewall 1425 with portions of materials 1422 and 1423 of cavities 1110) of cavities 1110.

The material of charge storage structures 1430 can include, for example, semiconductor material (e.g., polysilicon), dielectric charge trapping material, such as silicon nitride or other dielectric charge trapping materials. During removing (e.g., etching) a portion of the material that forms charge storage structures 1430, portions 1401 of material 1001 located over pillars 705 can also be removed to reduce the thickness of portions 1401.

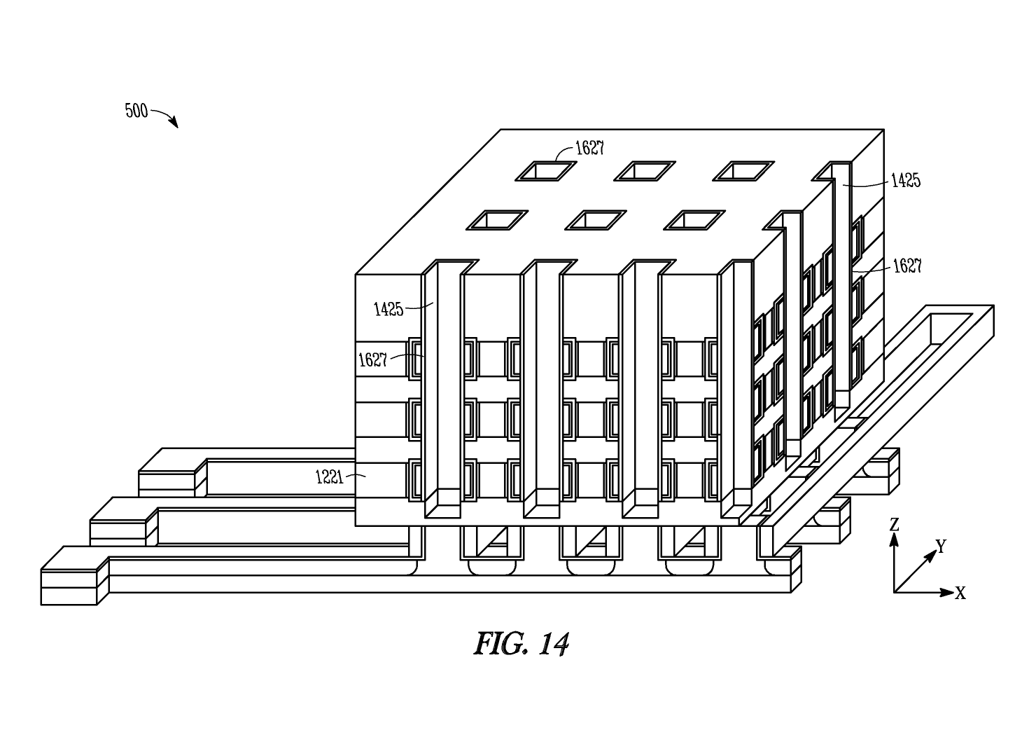

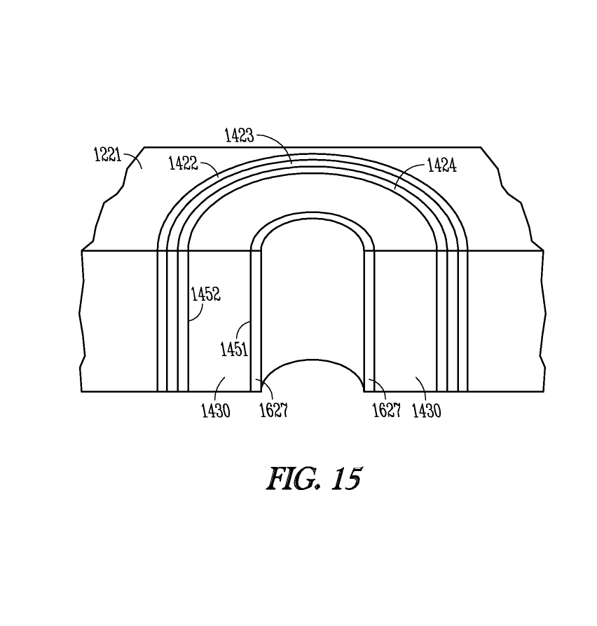

FIG. 14 and FIG. 15 show the process of constructing the memory device 500 after dielectric 1627 has been formed on inner side 1451 of charge storage structures 1430 and in cavities 1110. Forming dielectric 1627 can include depositing dielectric material (e.g., silicon oxide) on inner side 1451. Alternatively and/or additionally, forming dielectric 1627 can include oxidizing a portion (e.g., inner side 1451) of charge storage structures 1430. Forming dielectric 1627 (e.g., by oxidation) may also consume material 1423 formed on material 1422, which formed on sidewall 1425 of cavities 1110. Thus, dielectric 1627 may also form in cavities 1110.

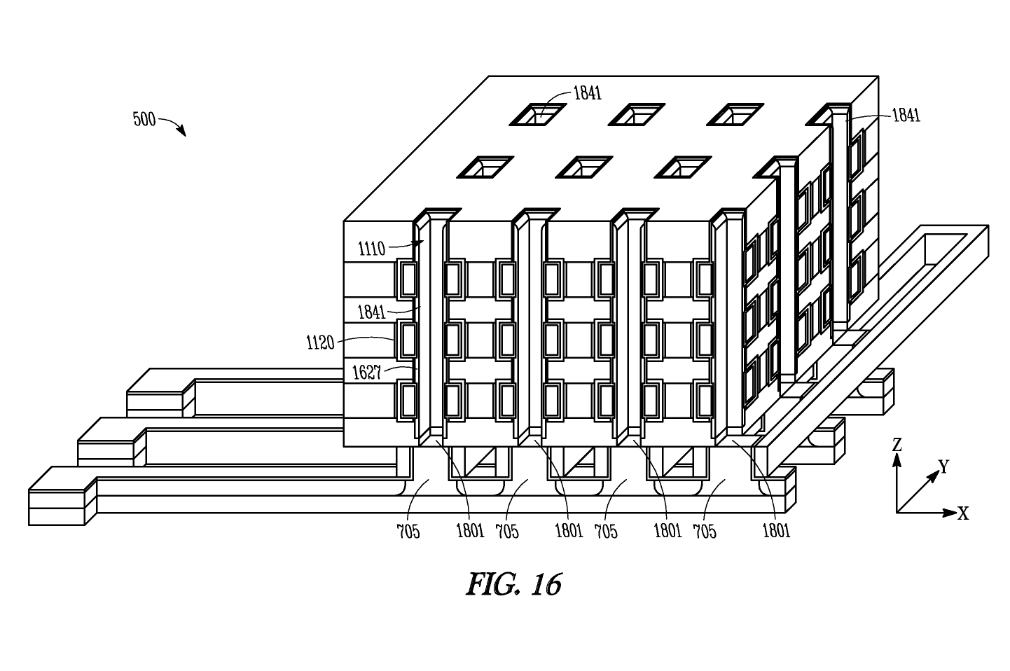

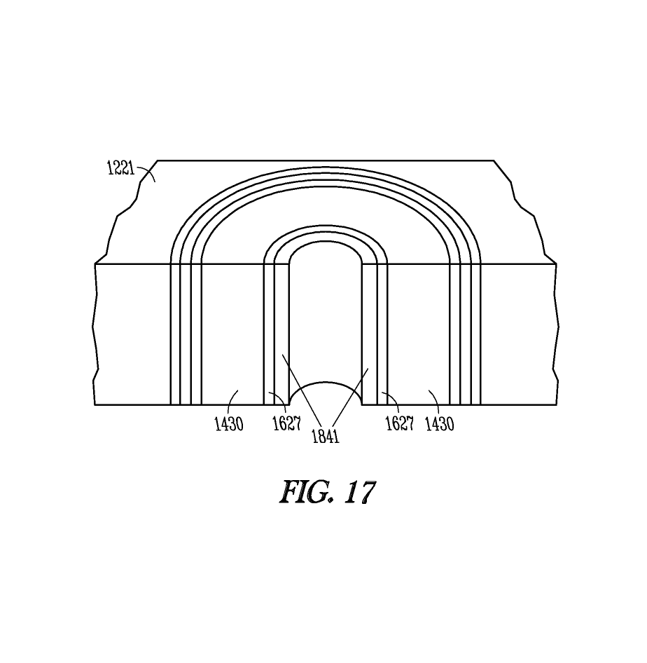

FIG. 16 and FIG. 17 show the process of constructing the memory device 500 after channels 1841 have been formed on dielectrics 1627 in both cavities 1110 and 1220. Forming channels 1841 can include depositing a conductive material on dielectrics 1627. An etching process can be used to reduce the thickness of the conductive material after it is deposited. The conductive material of channels 1841 can include doped polysilicon, which can have the same material type (e.g., p-type) as pillars 705 and/or the control gates. FIG. 16 also shows formation of the openings 1801, by removing (e.g., by etching) portions 1401 (FIG. 12) located over pillars 705. As shown in FIG. 17, channel 1841 is facing charge storage structures 1430 and is electrically isolated from each charge storage structure 1430 by at least a portion of dielectric 1627.

FIG. 18 shows the construction process of the memory device 500 after a conductive material 2001 has been formed by, for example, depositing undoped or lightly doped polysilicon that individually or collectively with material 1841 form pillars that are in electrical communication with pillars 705. As shown in FIG. 18, conductive material 2001 forms a continuous conductive path between channels 1841 and data lines 651, 652, and 653 through pillars 705.

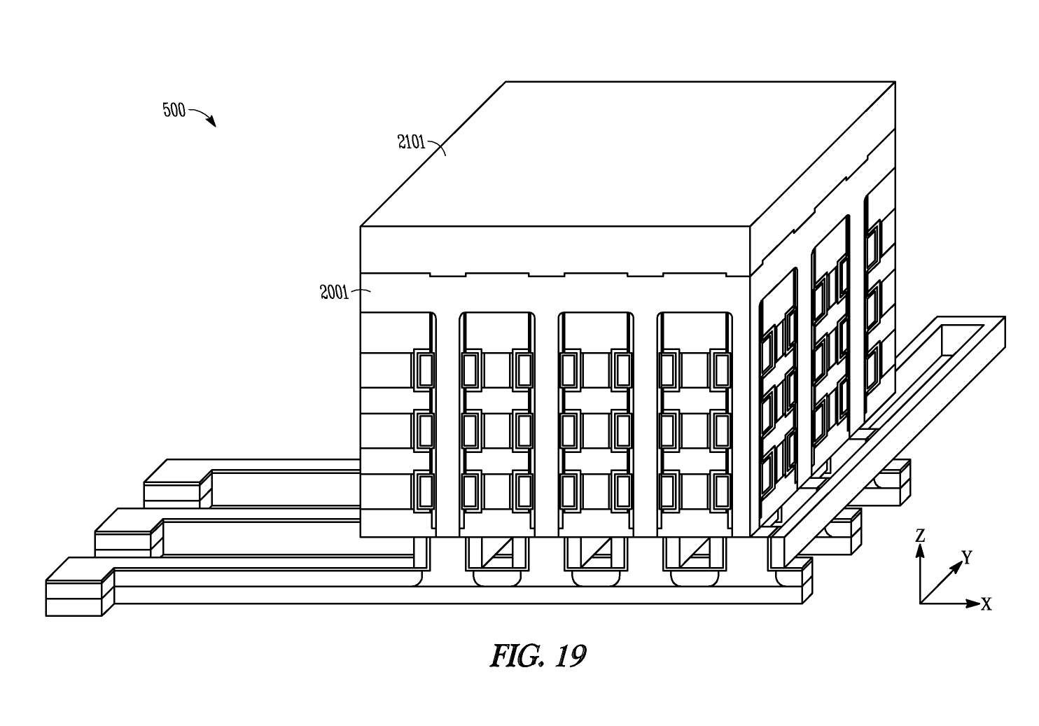

FIG. 19 shows the construction process of the memory device 500 after dielectric material 2101 (e.g., silicon oxide) has been formed over the conductive material 2001.

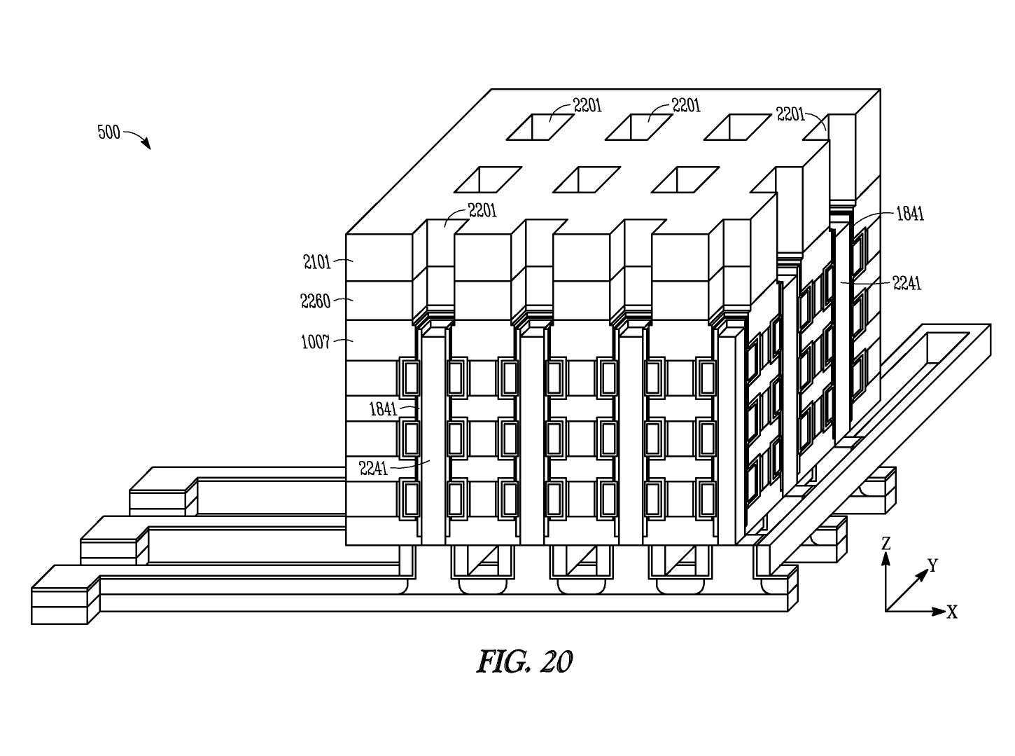

FIG. 20 shows the construction process of the memory device 500 after the formation of openings (e.g., holes 2201). Holes 2201 are formed such that each hole 2201 can be aligned substantially directly over channels 1841, as illustrated in FIG. 19. Forming holes 2201 can include removing (e.g., etching) a portion of dielectric material 2101 and a portion of conductive material 2001 (FIG. 19), stopping at a location in material 1007. Holes 2201 can be formed such that after a portion of conductive material 2001 is removed during the formation of holes 2201, conductive material 2001 is separated into conductive material portion 2260 and conductive material portions 2241, as illustrated in FIG. 20.

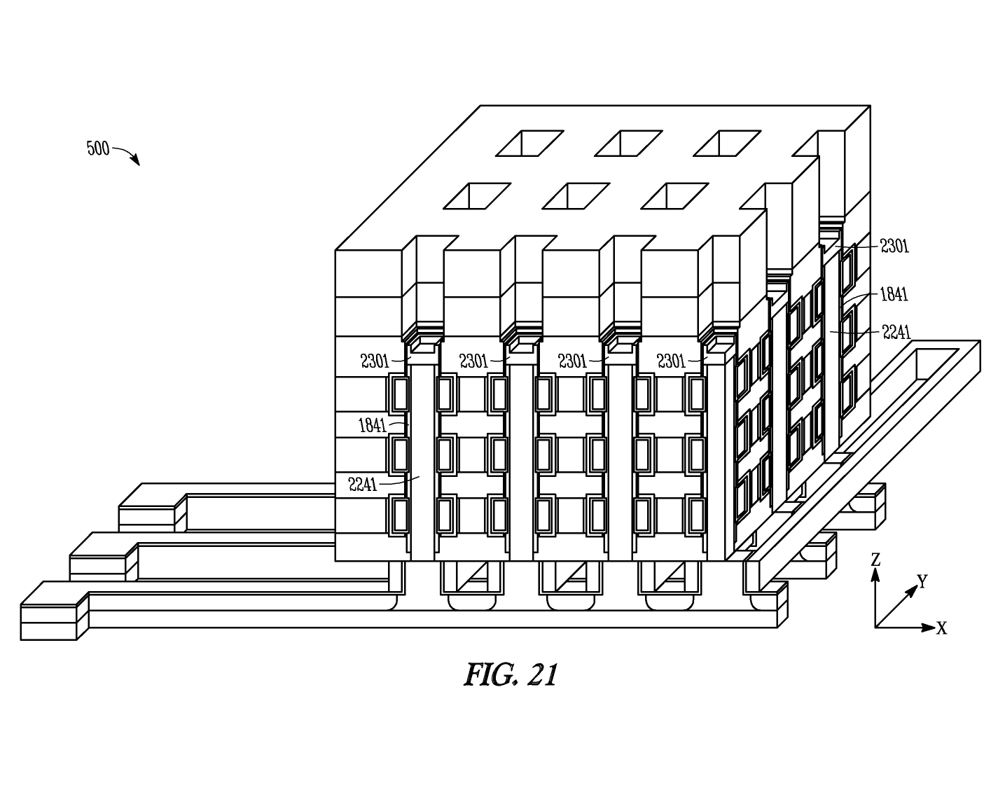

FIG. 21 shows the construction process of the memory device 500 after doped regions 2301 have been formed. Forming doped regions 2301 can include inserting (e.g., implanting) n-type impurities into top parts of conductive material portions 2241. Doped regions 2301 can provide a relatively low resistance connection between channels 1841 and other components of memory device 500.

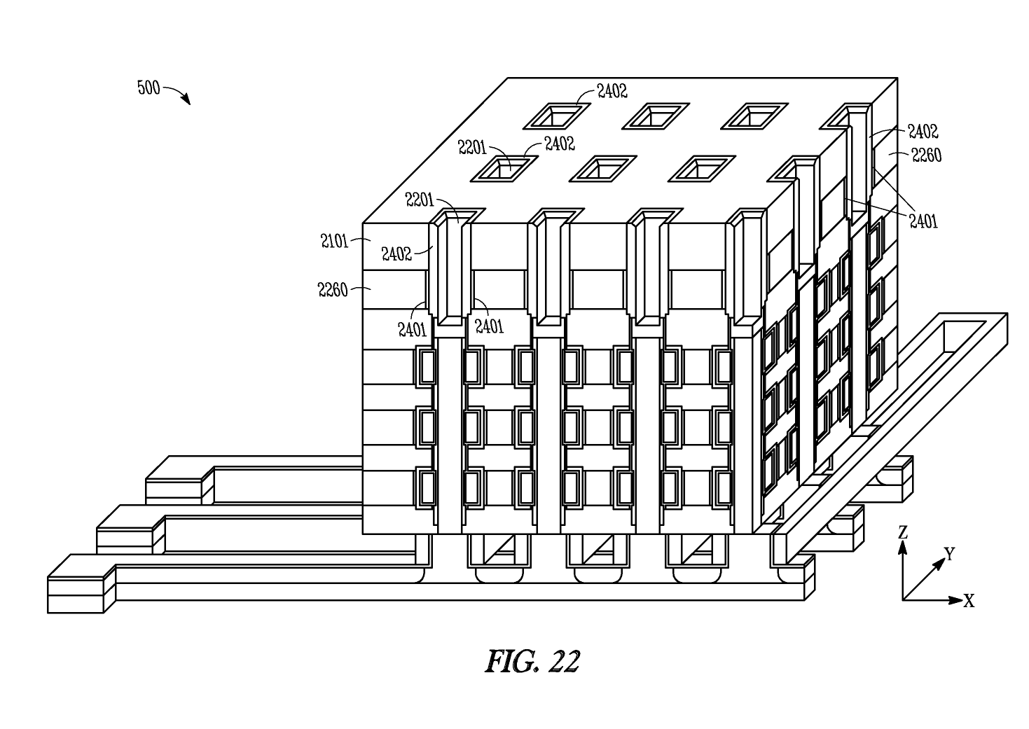

FIG. 22 shows the construction process of the memory device 500 after dielectrics 2401 and channels 2402 have been formed. Dielectrics 2401 (e.g., silicon oxide) is formed on sidewalls of conductive material portion 2260 at the location of holes 2201. Channels 2402 are formed on sidewalls of dielectric material 2101 and on dielectrics 2401.

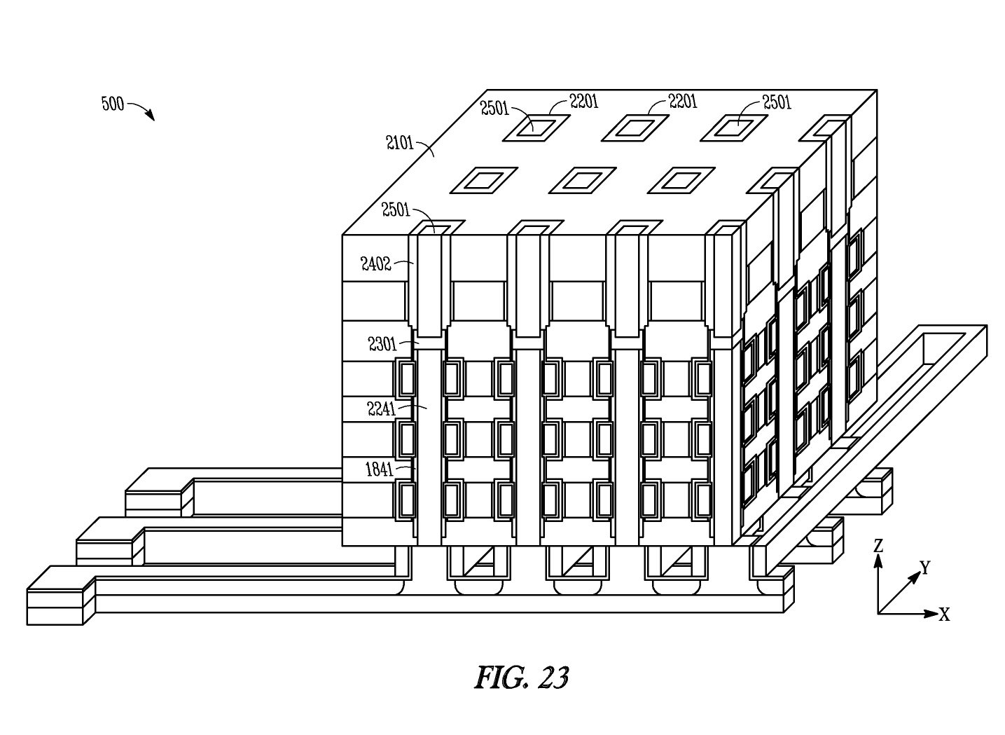

FIG. 23 shows the construction process of the memory device 500 after conductive material 2301 has been formed in each of holes 2201, such that channel 2402 can be electrically coupled to channel 1841 through conductive material 2301, doped region 2301, and conductive material portion 2241. Forming conductive material 2301 in each of holes 2201 can include depositing a conductive material (e.g., polysilicon) so that the conductive material fills holes 2201. Then, a top portion of the conductive material can be removed by, for example, etching back the conductive material or by chemical mechanical planarization (CMP).

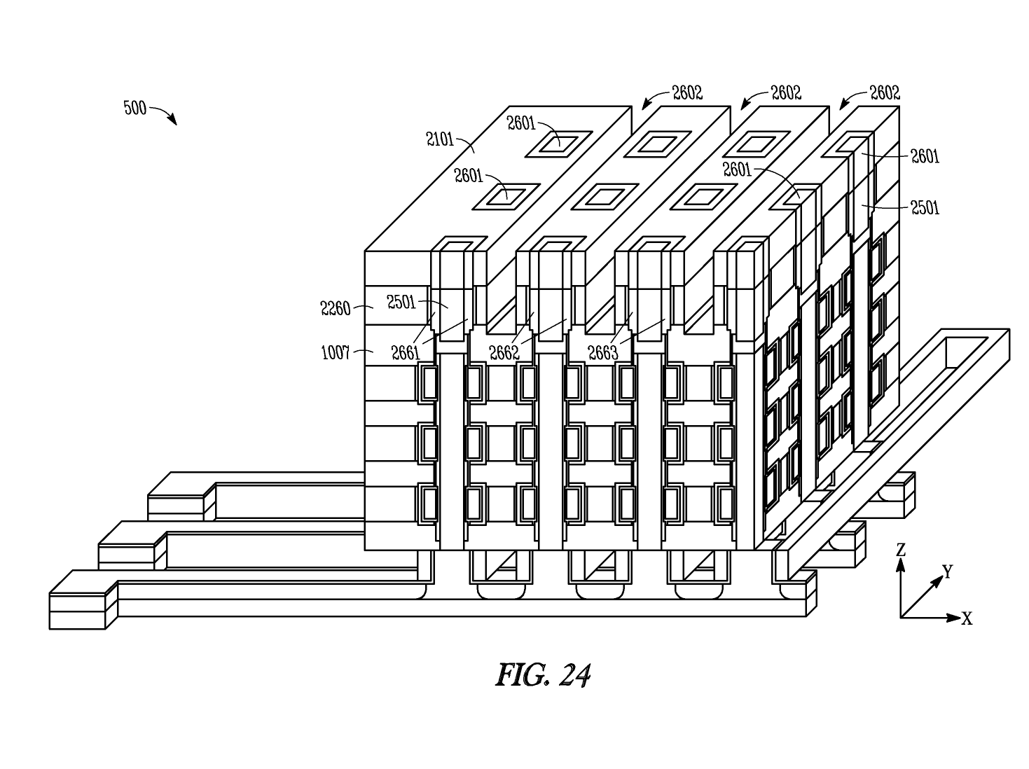

FIG. 24 shows the construction process of the memory device 500 after doped regions 2601 and source select gate lines 2661, 2662, and 2663 have been formed. Forming doped regions 2601 can include inserting (e.g., implanting) n-type impurities into top portions of conductive material 2301. Forming source select gate lines 2661, 2662, and 2663 can include removing parts of dielectric material 2101 and conductive material portion 2260 to form trenches 2602, which have trench bottoms partially extending into material 1007. As shown in FIG. 24, trenches 2602 separate conductive material portion 2260 into source select gate lines 2661, 2662, and 2663.

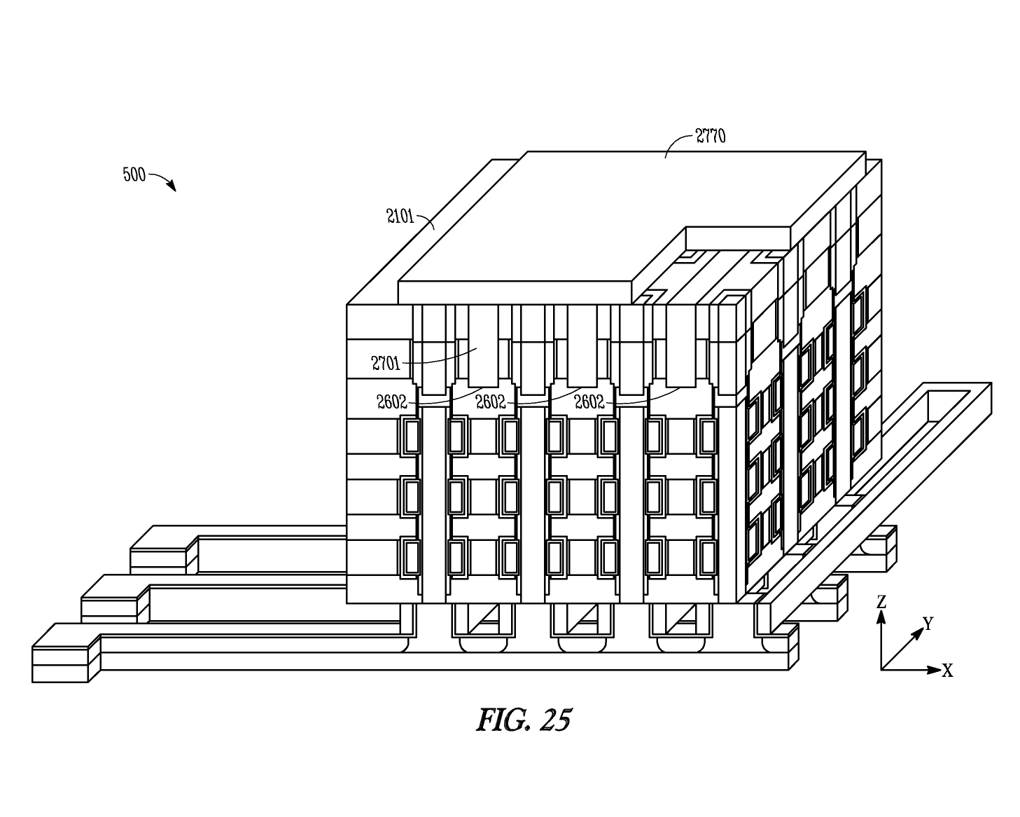

FIG. 25 shows the construction process of the memory device 500 after material 2701 and a common source 2770 have been formed. Forming material 2701 can include depositing a dielectric material (e.g., silicon dioxide) over material 2101, such that the dielectric material fills trenches 2602. Then, a top portion of the dielectric material can be removed by, for example, etching back the dielectric material or by CMP. Forming common source 2770 can include depositing a conductive material (e.g., metal) over materials 2701 and 2101.

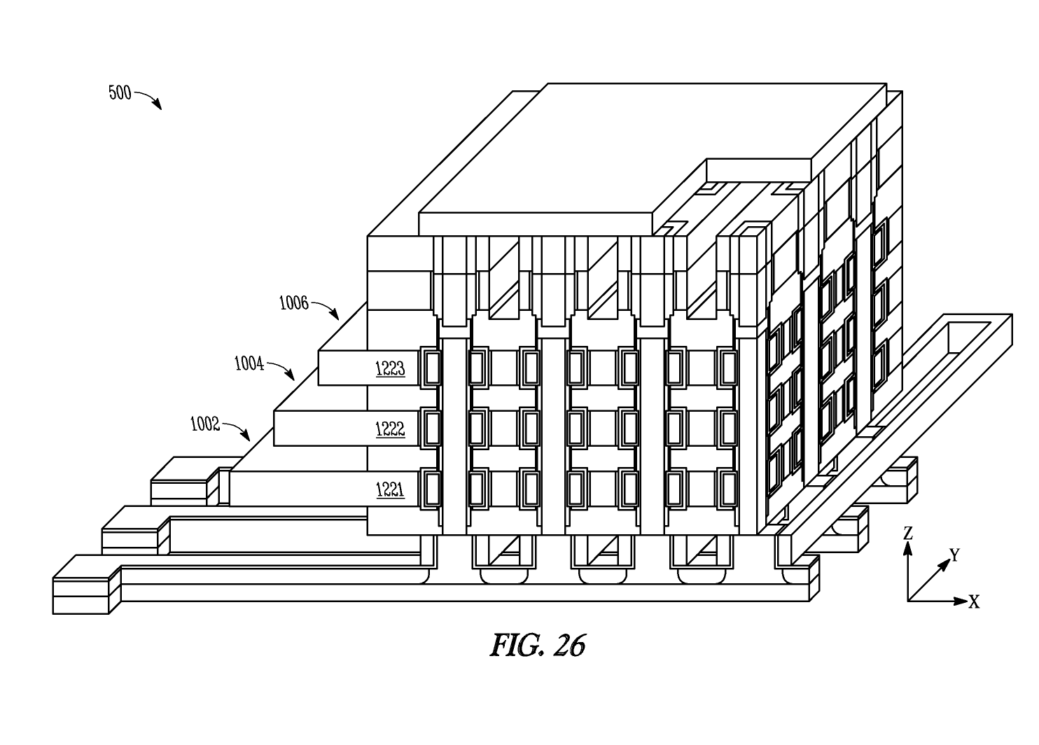

FIG. 26 shows the construction process of the memory device 500 after materials 1001 through 1007 in area 702 (FIG. 7) are processed (e.g., by patterning) to form a stair-like pattern. In an embodiment material (e.g., dielectric material, silicon dioxide) can fill areas between the stairs (not shown). As mentioned above in the description of FIG. 11, some portions of materials 1001 through 1007 are omitted from area 702 of FIG. 11 through FIG. 25 for clarity. FIG. 26 shows material 1001 through 1007 in area 702 after they have been processed to form the stair like pattern. As shown in FIG. 26, recessed gates 1221, 1222, and 1223 are formed from materials 1002, 1004, and 1006, respectively, which are formed in the stair like pattern.

FIG. 27 shows the memory device 500 when construction is complete, after contacts 2929, 2949, and 2959 have been formed. Contacts 2929 provide electrical connections to recessed gates 1221, 1222, and 1223. Contacts 2949 provide electrical connections to data lines 651, 652 and 653. Contacts 2959 provide electrical connections to and from data lines 651, 652, and 653.

As shown in FIG. 27, memory device 500 can include components and memory cells 2910, 2911, and 2912 similar to or identical to components and memory cells 110 of memory device 100 described above with reference to FIG. 1.

One of ordinary skill in the art may now recognize that additional processes may be performed to form additional features of a memory device, such as memory device 300 described above.

One or more embodiments described herein include a memory device and methods of forming the memory device. The various illustrations of the methods and apparatuses are intended to provide a general understanding of the structure of various embodiments and are not intended to provide a complete description of all the cells and features of the apparatuses and methods that might make use of the structures, features, and materials described herein.

The apparatuses of the various embodiments may include or be included in, for example, electronic circuitry used in high-speed computers, communication and signal processing circuitry, single or multi-processor modules, single or multiple embedded processors, multi-core processors, data switches, and application-specific modules including multilayer, multi-chip modules, or the like. Such apparatuses may further be included as sub-components within a variety of electronic systems, such as televisions, cellular telephones, personal computers (e.g., laptop computers, desktop computers, handheld computers, tablet computers, etc.), workstations, radios, video players, audio players, vehicles, medical devices (e.g., heart monitors, blood pressure monitors, etc.), set top boxes, and various other electronic systems.

A person of ordinary skill in the art will appreciate that, for this and other methods (e.g., programming or read operations) disclosed herein, the activities forming part of various methods may be implemented in a differing order, as well as repeated, executed simultaneously, or substituted one for another. Further, the outlined acts and operations are only provided as examples, and some of the acts and operations may be optional, combined into fewer acts and operations, or expanded into additional acts and operations without detracting from the essence of the disclosed embodiments.

The present disclosure is therefore not to be limited in terms of the particular embodiments described in this application, which are intended as illustrations of various aspects. For example, instead of using floating gates as a charge storage structure, charge traps may be used instead. Many modifications and variations can be made, as will be apparent to a person of ordinary skill in the art upon reading and understanding the disclosure. Functionally equivalent methods and apparatuses within the scope of the disclosure, in addition to those enumerated herein, will be apparent to a person of ordinary skill in the art from the foregoing descriptions. Portions and features of some embodiments may be included in, or substituted for, those of others. Many other embodiments will be apparent to those of ordinary skill in the art upon reading and understanding the description provided herein. Such modifications and variations are intended to fall within a scope of the appended claims. The present disclosure is to be limited only by the terms of the appended claims, along with the full scope of equivalents to which such claims are entitled. It is also to be understood that the terminology used herein is for the purpose of describing particular embodiments only and is not intended to be limiting.

The Abstract of the Disclosure is provided to comply with 37 C.F.R. §1.72(b), requiring an abstract allowing the reader to quickly ascertain the nature of the technical disclosure. The abstract is submitted with the understanding that it will not be used to interpret or limit the claims. In addition, in the foregoing Detailed Description, it may be seen that various features are grouped together in a single embodiment for the purpose of streamlining the disclosure. This method of disclosure is not to be interpreted as limiting the claims. Thus, the following claims are hereby incorporated into the Detailed Description, with each claim standing on its own as a separate embodiment.

1.-8. (canceled)

9. A method comprising:
etching polysilicon selective to oxide to form a recessed control gate having a surface with a nub; and
applying a smoothing solution to the surface of the recessed control gate to smoothen the nub.

10. The method of claim 9, wherein applying the smoothing solution includes applying a solution comprising an acid.

11. The method of claim 9, wherein applying the smoothing solution includes applying a solution comprising nitric acid.

12. The method of claim 9, wherein applying the smoothing solution includes applying a solution comprising oxalic acid up to 10 weight percent (wt %) of the smoothing solution.

13. The method of claim 9, wherein applying the smoothing solution includes applying a solution comprising hydrofluoric acid up to 0.5 wt % of the smoothing solution.

14. The method of claim 9, wherein etching polysilicon comprises forming the recessed control gate by multiple cycling of vapor phase chemistry.

15. The method of claim 9, wherein etching polysilicon comprises etching the polysilicon with vapor fluorine, vapor ammonia, or combinations thereof.

16. The method of claim 9, wherein the smoothing includes smoothing the outer surface for a particular time, the particular time based on a threshold oxide loss value.

17. The method of claim 9, wherein etching polysilicon is selective to oxide and comprises enlarging a cavity formed in the polysilicon.

18. The method of claim 9, wherein etching polysilicon comprises etching heavily boron doped polysilicon.

19. The method of claim 18, wherein etching heavily boron doped polysilicon comprises etching polysilicon doped with about 1×10²¹ boron atoms/cm³.

20. The method of claim 9, wherein applying a smoothing solution to the surface of the recessed control gate to smoothen the nub comprises applying a solution that comprises nitric acid, a complexing agent, and hydrofluoric acid.

21. The method of claim 9, wherein applying a smoothing solution to the surface of the recessed control gate to smoothen the nub comprises applying a solution that comprises nitric acid, deionized water, and hydrofluoric acid.

22. A method comprising:
forming a first material, wherein the first material is conductive;
forming a second material over the first material, wherein the second material is a dielectric;
forming a third material over the second material, wherein the third material is conductive;
forming an opening in the first, second and third materials, wherein the opening comprises a first cavity in the first material, a second cavity in the second material, and a third cavity in the third material;
enlarging the first and third cavities to form recessed control gates out of the first and third materials; and
smoothing the recessed control gates in each of the first and third cavities.

23. The method of claim 22, wherein forming a first material comprises forming heavily boron doped polysilicon, and forming a third material comprises forming heavily boron doped polysilicon material.

24. The method of claim 23, wherein forming heavily boron doped polysilicon comprises forming polysilicon doped with about 1×10²¹ boron atoms/cm³.

25. The method of claim 22, wherein enlarging the cavities includes performing an oxide selective etching process.

26. The method of claim 22, wherein smoothing the recessed control gates comprises applying a smoothing solution to the first and third cavities, wherein the smoothing solution comprises nitric acid and hydrofluoric acid.

27. The method of claim 26, wherein the smoothing solution further comprises deionized water.

28. The method of claim 26, wherein the smoothing solution further comprises a complexing agent.

29. The method of claim 28, wherein the complexing agent comprises oxalic acid.
